(19) United States
(12) Patent Application Publication
(10) Pub. No.: US 2010/0305889 A1
(43) Pub. Date: Dec. 2, 2010

(54) NON-INTRUSIVE APPLIANCE LOAD IDENTIFICATION USING CASCADED COGNITIVE LEARNING

(75) Inventors: Harold Woodruff Tomlinson, JR., Ballston Spa, NY (US); Michael Richard Durling, Saratoga Springs, NY (US); Rashi Tiwari, Piscataway, NJ (US); Yaser Khalifa, New Paltz, NY (US)

Correspondence Address: GENERAL ELECTRIC COMPANY;GLOBAL RESEARCH, ONE RESEARCH CIRCLE, BLDG. K1-3A59, NISKAYUNA, NY, 12309, US

(73) Assignee: GENERAL ELECTRIC COMPANY, SCHENECTADY, NY (US)

(21) Appl. No.: 12/472,650

(22) Filed: May 27, 2009

(51) Int. Cl. G06F 19/00; G01R 21/00

(52) U.S. Cl. 702/62

(57) ABSTRACT

A method of identifying energy consumption associated with at least one appliance is provided. The method includes measuring an energy consumption signal, obtaining publicly available information of a location of the at least one appliance and estimating a plurality of probabilities of energized appliances based on the energy consumption signal and the publicly available information. The method further includes generating a new combination of the estimated plurality of probabilities of energized appliances and decomposing the at least one energy consumption signal into constituent individual loads and corresponding energy consumption.

### BACKGROUND

This invention relates generally to electric energy consumption measurement, and, more specifically, to load identification using cascaded cognitive learning.

With the rising cost of energy/electricity, consumers are becoming more conscious of their consumption and more thoughtful in terms of sustainable energy planning. An itemized electricity bill indicating the energy consumption of each household appliance would provide useful information for consumers to consider. However, customers do not want to incur the expense of additional energy meters for measuring energy or power consumption of individual appliances. Non-intrusive appliance load monitoring (NIALM) has been attempted to identify electric appliances in a small building, such as a household, by monitoring a load profile signature of the whole household load at a single point with one recording device (that is, without individual meters on the appliances).

One product that decomposes a signal measured at an incoming power meter into its constituent individual loads is known as Single Point End-use Energy Disaggregation (SPEED™), and is available from Enetics, Inc. of New York. The SPEED product uses an appliance template to describe the operating characteristics of appliances likely to be found in the home. If the appliance characteristics fall within the template parameters, the system can identify the appliances fairly well. Unfortunately, given the wide range of appliance parameters in the industry, the system has trouble identifying individual appliances in a high percentage of installations without modifying the template parameters.

Another embodiment is described in commonly assigned US20090045804, which is herein incorporated by reference, wherein one embodiment is directed to an electric power meter comprising: at least one sensor configured to measure at least one desired energy consumption variable associated with a plurality of energy consumption devices and a decomposition module configured to decompose at least one output signal from the sensor into constituent individual loads and therefrom identify energy consumption corresponding to each energy consumption device. In one example, the power meter includes data fusion from multiple diverse sensors such as time, date, temperature, security systems, TVs, and computer networks to provide enhanced load definitions and does not require field training of parameters to generate desired results. The power meter, in one embodiment, is configured to communicate directly with smart appliances over a power line carrier, a wireless link, or other suitable communication means.

Although several decomposition techniques have been proposed, a need still exists for a more comprehensive electric energy/power meter.

### BRIEF DESCRIPTION

In accordance with an exemplary embodiment of the present invention, an energy measurement system comprises: at least one sensor configured to measure at least one output signal associated with a plurality of appliances; an orientation module configured to gather publicly available information associated with a location of the appliances; a planning module configured to generate an appliance database based on an input signal from the orientation module; a decomposition module configured to decompose the at least one output signal into constituent individual loads and therefrom identify energy consumption corresponding to each appliance based on the appliance database; and a communication interface configured to transmit the decomposed output signal.

In accordance with another exemplary embodiment of the present invention, a method of identifying energy consumption associated with at least one appliance is provided. The method includes measuring an energy consumption signal, obtaining publicly available information of a location of the at least one appliance and estimating a plurality of probabilities of energized appliances based on the energy consumption signal and the publicly available information. The method further includes generating a new combination of the estimated plurality of probabilities of energized appliances and decomposing the at least one energy consumption signal into constituent individual loads and corresponding energy consumption.

In accordance with yet another exemplary embodiment of the present invention, an energy measurement system is provided. The system includes at least one sensor configured to measure at least one output signal associated with a plurality of appliances and a communication interface configured to transmit the at least one output signal to a remote utility station. The system further includes an orientation module configured to gather publicly available information associated with a location of the appliances and a planning module to generate an appliance database based on an input signal from the orientation module. A decomposition module is also provided in the system to decompose the at least one output signal into constituent individual loads and therefrom identify energy consumption corresponding to each appliance based on the appliance database. The orientation module, the planning module and the decomposition module are located at the remote utility station.

### DRAWINGS

These and other features, aspects, and advantages of the present invention will become better understood when the following detailed description is read with reference to the accompanying drawings in which like characters represent like parts throughout the drawings, wherein:

FIG. 1 is a diagrammatical representation of an energy measurement system with a cognitive electric energy meter in accordance with an embodiment of the present invention;

FIG. 2 is a diagrammatical representation an example itemized electric bill;

FIG. 3 is a diagrammatical representation of a cognitive electric energy meter system broken into components in accordance with an embodiment of the present invention;

FIG. 4 is a diagrammatical representation of a cognitive decomposition algorithm in accordance with an embodiment of the present invention; and

FIG. 5 is a diagrammatical representation of an exemplary cascaded Bayesian network in accordance with an embodiment of the present invention.

### DETAILED DESCRIPTION

As discussed in detail below, embodiments of the present invention function to provide a system and a method that employs intelligence to decompose an energy signal measured at a meter into its constituent individual loads and to provide a usage summary to the consumer with no in home field installation cost and with no requirements for special sensors, interactions with the loads, or specifications on the loads.

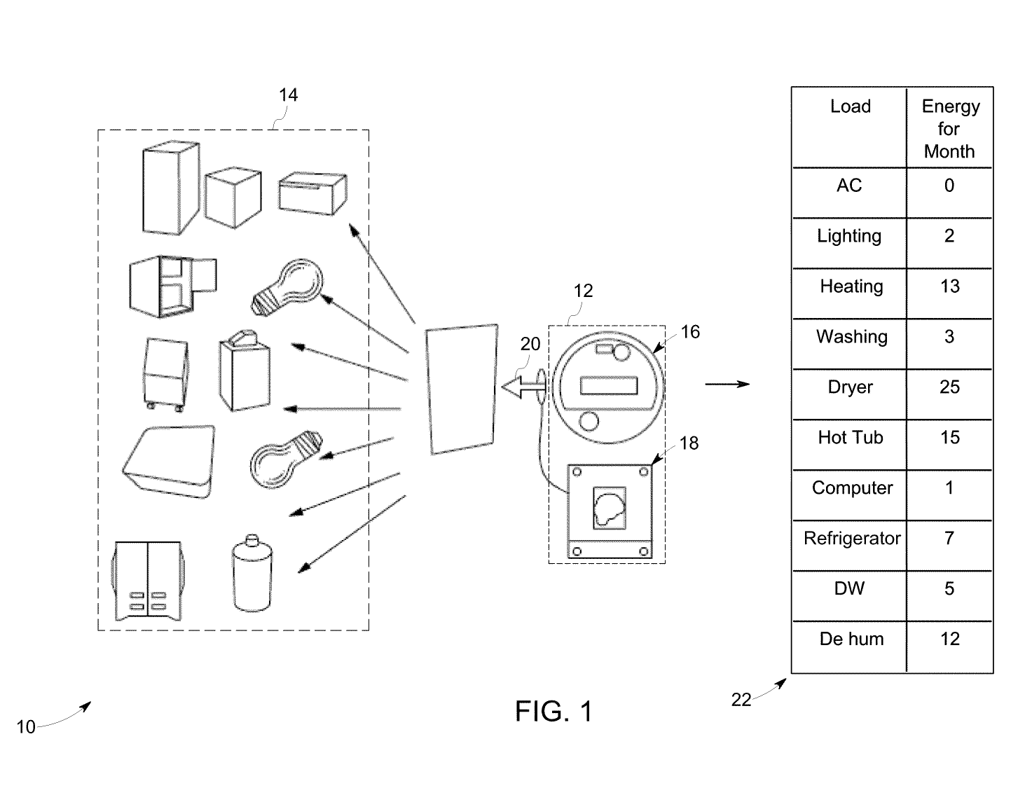

FIG. 1 shows an energy measurement system 10 with a cognitive electric energy meter 12 in accordance with an embodiment of the present invention. FIG. 1 further illustrates various electrical loads 14 in a household. In one embodiment, the electric energy meter 12 includes voltage and current sensors or an energy sensor 16 and an intelligence unit 18 to decompose one measured load signal or energy consumption signal 20 into its constituents 22. It should be noted here that the shown measured constituents 22 in FIG. 1 are exemplary and that the measured constituents depend on the actual electrical load in the household. The cognitive electric energy meter 12 uses model based intelligence to decompose the load signal that is already measured at the incoming meter 16 into its constituent individual loads and may be used to provide a usage summary to the consumer with no in home installation of additional sensors. The intelligence unit 18 may be co-located with the energy meter 16 or may be at a location away from the energy meter 16. It should be noted that the terms energy meter and the power meter have been used here interchangeably as energy can be determined by multiplying the power by the time.

The cognitive electric power meter 12 allows a power utility provider to provide the consumer with a detailed electric bill showing individual loads usage, without requiring installation of invasive and expensive sensors on each of the branch circuit loads. This may be used to provide the consumer with a first order and persistent energy audit each month in order to help the consumer know how electricity is being used, and may drive conservation, maintenance, or appliance upgrade decisions.

A typical consumer electric bill shows simply the difference between the meter reading at the beginning and end of the month to calculate total energy consumption, and then may provide a comparison to last year's bill for the similar period as well as previous monthly energy consumption statistics.

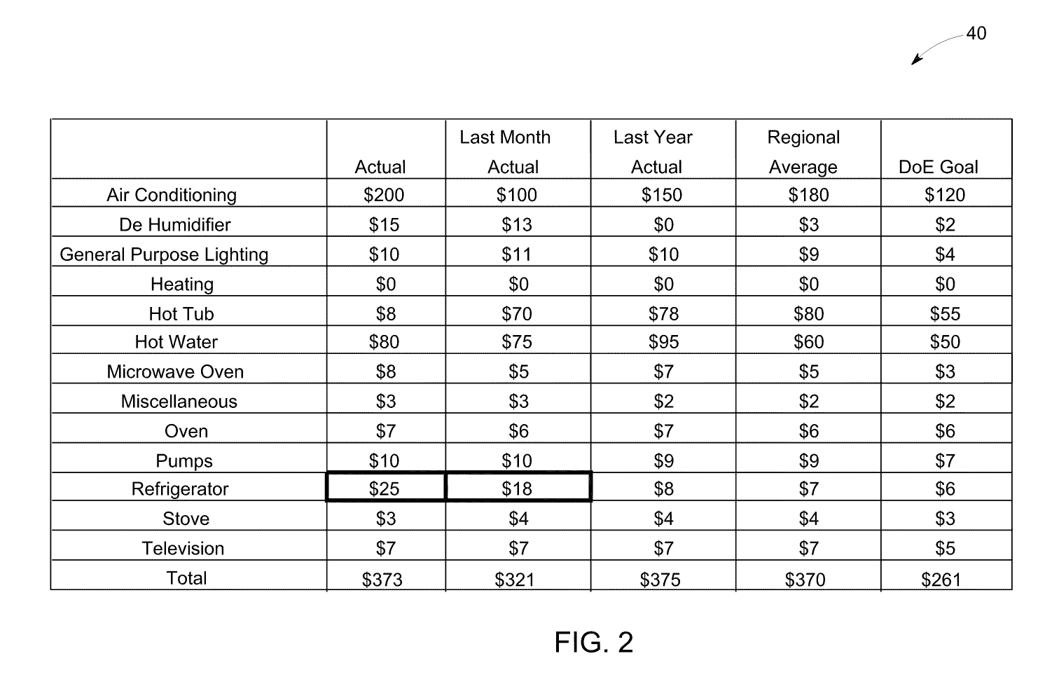

As described in aforementioned US20090045804 and shown in FIG. 2, an exemplary itemized electric bill 40 may provide an estimate for each of the electric loads typically found in a home, a comparison to local peers for the same period, the national average, and the Department of Energy (DoE) goal. Such bills can serve as a first order energy audit to enable consumers to make better decisions about investing in new and more efficient technologies.

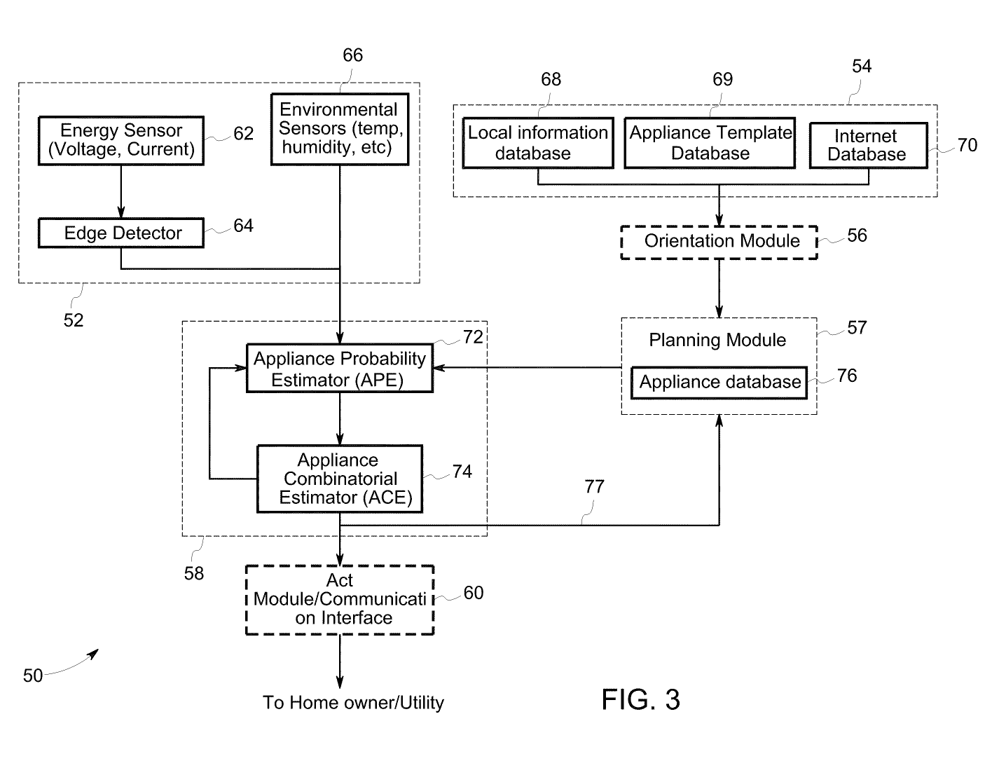

FIG. 3 shows a cognitive electric energy measurement system 50 broken into components in accordance with an embodiment of the present invention. The system 50 includes a sensing module 52, a database module 54, an orientation module 56, a planning module 57, a decomposition module 58, and an act module/communication interface 60. The sensing module 52 typically includes energy sensors 62, edge detector circuitry 64 for the energy sensors, and may further include environmental sensors 66; the database module 54 may include a local information database 68, an appliance template database 69 and an Internet database 70. The decomposition module 58 may include an appliance probability estimator 72 and appliance combinatorial estimator 74.

The energy sensors 62 include meters for measuring voltages, currents, admittances or impedances from any two phases and a neutral wire at the consumer location and may be used for computing instantaneous power and thus providing an energy consumption signal. Energy sensors 62 typically further include a timer to measure the time of day and date. In an alternative embodiment, the time and date information may be obtained from one or more sources such as a radio, wire, IP network, or other means. The date and time data can be used to help reduce error and to simplify the cognitive decomposition algorithms. In another embodiment, real and reactive admittance data or impedance data may be calculated from the measured voltages and currents, and significant step changes in admittance data or impedance data may then be identified. Real and reactive step changes, or edge data, refers to the change in admittance or impedance or power measured by the voltage and current sensors in the sensing module 52 every time an appliance turns ON or OFF. In one embodiment, the environmental sensors 66, such as temperature and humidity sensors may be used, or such data may be obtained from database module 54. The observed and estimated data from the sensing module 52 is supplied to the decomposition module 58. In one embodiment, the decomposition module uses knowledge of installation location of the cognitive energy meter system to gather additional Meta data related to the customer site. Hence, in one embodiment, the location data is configured in the local information database 68 by the utility at installation time. In another embodiment, a global positioning system (GPS) module may be used along with the sensing module to detect the consumer location data.

In the embodiment of FIG. 3, the decomposition module 58 further utilizes inputs from an appliance database 76. The orientation module 56 collects data from the local database 68, the Internet database 70 and the appliance template database 69 and provides it as an input signal to the planning module 57, which then processes the data to generate the appliance database 76. The local database 68, when available, comprises information regarding types of appliances and number of appliances in the house and the house location. In one embodiment, the Internet databases 70 may include aerial imagery of a house from a Google Maps™ mapping service or the house details from Zillow.com® real estate service. The information obtained from Internet databases may be used to determine if the consumer location has a swimming pool in the backyard or to find out home details such as home value, square footage, number of stories, number of bedrooms and bathrooms, type of heating and cooling system, and year built, for example. If environmental sensors 66 (such as temperature and humidity sensors) are not present, environmental data may be obtained by internet databases 70, if desired. The appliance template database 69 has information regarding the typical maximum and minimum power levels for appliances, and typical duty cycles of appliances. The planning module 57 uses the data received by orientation module 56 from the databases 68, 69, 70 to fill the appliance database with the probability that a particular appliance is installed in the house, and the probability it is on during a specific time (season, time-of-day, etc). In one embodiment, the probability is based on the size of the home, location, type of heating and cooling system, swimming pool availability, number of bedrooms and bathrooms, and whether or not city water exists or a well is required. It should be noted that the above parameters to build the appliance database are exemplary and any other such parameters may also be used to build the probability model. The appliance database is then fed as input to the decomposition module 58.

The decomposition module 58, in an exemplary embodiment, comprises an Appliance Probability Estimator (APE) 72 and an Appliance Combinational Estimator (ACE) 74. APE 72 is used for estimating the appliance state matrix (ON or OFF), which contains the estimated state for each possible appliance in the home, given data from the appliance database 76 and measured data from sensing module 52. APE 72 also computes the confidence in the state matrix estimate and estimates the total power in the home based on the appliance state and the nominal power consumption of the appliance. The ACE 74 takes the outputs from the APE 72 and computes the difference between the total measured power in the home and the estimated power consumed in the home. If the residual power value is less than a power threshold, the current appliance state matrix is accepted. If not, a new combination of possible appliances in the home is generated by ACE 74, and the new combination of appliances is fed back as input to APE 72. In one embodiment, a genetic algorithm is used to generate a new combination of appliances from possible appliances in the appliance database. In this way, the decomposition module 58 generates an appliance state matrix providing information about number of appliances and their states, on or off. In one embodiment, the probabilities of the appliance states determined in the appliance state matrix are compared with a confidence threshold and if the probability values are higher than the confidence threshold, the appliance database is updated with the measured values for average power level, duty cycle, etc. using a feedback loop 77. In one embodiment, the confidence threshold may have a value of 90% (in other words, the confidence of appliance state matrix being accurate is 90%). In this way, the cognitive meter 50 can learn the appliance parameters for the specific appliances in the home, instead of relying on the data from the appliance template database. The act module/communication interface 60 computes the energy usage of each appliance based in the appliance state and a time interval (nominally monthly), and communicates the results. In one embodiment, the communication is to the utility which then incorporates the information into the consumer's bill. In one embodiment, the communication interface 66 may include an RS232/USB/Firewire interface, an Ethernet interface, a Wifi interface, a wireless USB interface, or a cellular/WMAN interface. In one embodiment, the communication interface 66 may transmit the data from the sensing module 52 to a remote utility station and the database module 54, the orientation module 56, the planning module 57 and the decomposition module 58 may be installed at the remote utility station for decomposing the energy consumption signal into various appliance signals. In another embodiment, the processing is done within the meter itself with the communication interface being coupled from the meter to the utility or to the consumer, for example.

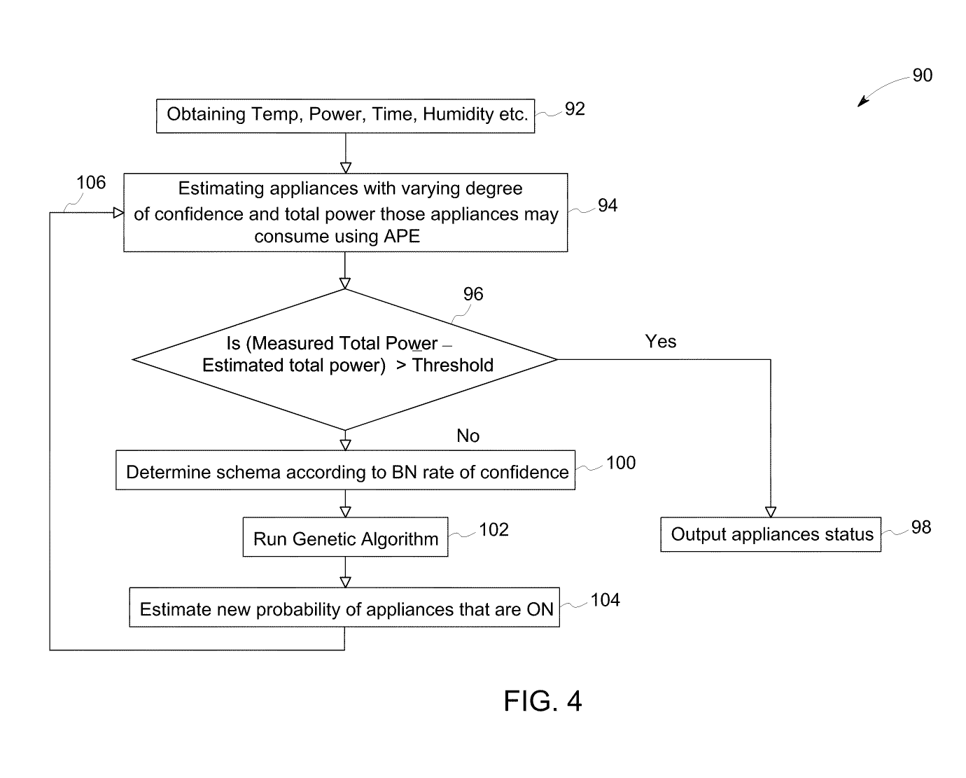

A more detailed description of the APE 72 and ACE 74 is provided below. FIG. 4 illustrates the cognitive decomposition algorithm 90 formed by the APE 72 and ACE 74 used in the decomposition module 58 of FIG. 3 in accordance with an embodiment of the present invention. Module 94 forms the APE 72, and Modules 96, 100, 102, 104 comprise the ACE 74. APE 72 uses a priori knowledge about the residence or commercial establishment such as dwelling size, dwelling age, occupant demographic, temperature, humidity, time, power measurement etc. obtained in step 92, as provided by Sensing Module 52 and Appliance Database 76. The data in step 92 may be obtained from public/internet databases and various sensors as described earlier. In step 94, the Appliance Probability Estimator (APE) (element 72 in FIG. 3) is used to estimate an appliance probabilistic model representing appliances detected with varying degrees or rates of confidence. In one embodiment, the APE utilizes a Bayesian Network (BN) algorithm. In another embodiment, other probabilistic techniques such as Markov Chain or Hidden Markov Model may alternatively or additionally be employed. The appliance probabilistic model estimates the appliance status, ON or OFF. It is achieved by monitoring changes in power levels or admittance or impedance on one or two phases in the system and associating them with the knowledge about the residential or commercial establishments and the typical power levels of appliance as provided by the appliance database 76. The APE determines the probability of an appliance being ON or being energized at the time of interest. It also determines the total power appliances may consume when ON. In one embodiment, the output of the APE may be a state matrix such as A=[1 0 1 0 1], wherein matrix A represents one appliance model and each element in the matrix represents a particular appliance. For example, first column of the matrix A may represent an Air Conditioner (AC) or the third column of the matrix A may represent a Pool Pump. Finally, the value of the matrix element represents the status of the particular appliance, with one example of 1 representing a corresponding appliance is ON and 0 representing the corresponding appliance is OFF. Thus, in one embodiment, the APE provides such a matrix with varying rates of confidence or probabilities. It also provides an estimate of the total power consumed in the house based on the appliance state and the nominal appliance power consumptions contained in the appliance database 76.

In step 96, the estimated total power computed from step 94 is compared against the total measured power. If the difference between the estimated total power and the measured total power is less than a power threshold value then the estimated appliance state matrix is provided as output in step 98. However, if the difference between estimated total power and the measured total power is higher than the power threshold, an Appliance Combinatorial Estimator (ACE) (element 74 in FIG. 3) is used to estimate a new probability of appliances as shown by blocks 100, 102 and 104 and by providing a learning feedback loop 106. In one embodiment, the ACE comprises a genetic algorithm (GA). As will be appreciated by those skilled in the art, a GA is a search technique used to find exact or approximate solutions to search problems, for example in this case, an appliance status matrix. In step 100, a schema is determined based on a BN rate of confidence. As will be appreciated by those skilled in the art, a schema is a template that identifies a subset of strings with similarities at certain string positions. In one embodiment, the schema may look like B=[1 * 1 * *] for the earlier example of matrix A. In one example, the schema includes all those appliance matrices or appliance combinations where the AC and the Pool Pump are ON.

In step 102, the genetic algorithm is run on the schema determined in step 100. In step 104, the new probabilities are estimated by; taking BN confidence rates from step 94 into consideration and finding combinations of appliances that would need to be ON to match total power measured at the meter preserving these appliances. The GA output from step 104 is then fed back into the BN of step 94 in a form of an evidence node. The node would provide a TRUE if GA suggests a particular appliance is ON, and FALSE if the GA suggests that the appliance is OFF. APE of step 94 then uses this information to re-estimate appliances' on/off status. The loop 106 continues until APE and ACE reach a stable set of appliances that are ON.

As will be appreciated by those skilled in the art, a BN is a directed graphical model, and the heart of the BN algorithm lies in the celebrated inversion formula,

$$p ( H \vert e ) = \frac{p ( e \vert H ) \cdot P ( H )}{P ( e )} \qquad ( 1 )$$

where, H and e are two events, while p(H|e) represents probability that event H will occur given event e. Similarly, p(e|H) represents probability of occurrence of event e given event H and p(H) and p(e) are general probabilities of events H and e respectively. In one embodiment, the event H may be that AC is ON and event e may be that the time is morning and outside temperature is low. Thus, in one embodiment, the probability of AC being ON given that the time is morning and the temperature is low may be computed by multiplying the previous belief of AC being ON p(H) by the likelihood events of time being morning and temperature being low p(e|H). The denominator in equation (1) is a normalizing constant that ensures the posterior adds up to 1. It should be noted here that the above events and the probabilities with given events are exemplary and other similar events and probabilities are in scope of the present algorithm.

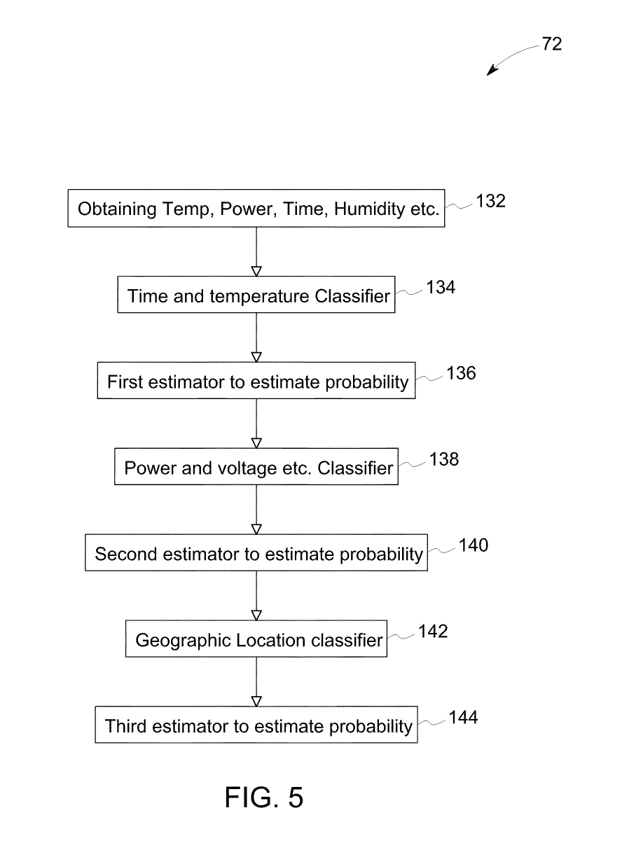

FIG. 5 illustrates an exemplary cascaded Bayesian network or APE 72 in accordance with an embodiment of the present invention. In step 132, the Bayesian network 72 obtains input from appliance database (element 76 of FIG. 3) containing temperature, power, time, and humidity etc. and provides this input to cascaded sub networks, which utilizes Bayesian statistics. In the first sub-network, a first classifier 134, such as a temperature and time classifier, classifies some appliances from the household and filters out remaining appliances along with their probabilities by the first estimator 136. The second network consists of a second classifier 138 for changes in power; such as a line voltage and load type (resistive, capacitive or inductive) classifier. The appliances from the first stage are then further filtered by a second estimator 140. A third classifier 142 of geographic location follows this stage and leads to further strengthening of the belief in the probability of selected appliances and their status by utilizing a third estimator 144. In another embodiment, all the classifiers may be combined into one classifier. The classifiers may also be referenced as nodes in one embodiment. The output of the third estimator 144 is then further provided to a step 96 of FIG. 4 and further to GA if needed as described earlier.

As will be appreciated by those skilled in the art, genetic algorithms use the principles of selection and evolution to solve a problem. The problem in the cognitive metering case is finding the best probabilistic model of appliances. In one embodiment, the genetic algorithm includes three steps: selection, crossover, and mutation. In the selection step, some elements from the Bayesian network are randomly selected based on the rate of confidence such that, the higher the rate of confidence, the higher the chance of being selected. The selected matrices are referred to as parent elements. For example, in one embodiment, the parent elements may be the matrices A=[1 0 1 0 1] and X=[0 0 0 1 1]. In the crossover step, a crossover point is selected for each of the parent elements, and new elements referred to as child elements are created from the parent elements. In one embodiment, the crossover may include a single point crossover, a multipoint crossover, or zero point crossover. In multipoint crossover many crossover points may be selected, whereas in zero point crossover no crossover point is selected and the parent element is selected as it is. As an example, if for the matrices A and X, a crossover point is selected as third column of the matrix then the child element may be a matrix Y=[A(3), X(2)]=[1 0 1 1 1]. In the mutation step, the parent elements as well as child elements are changed by a small amount. For example, in one embodiment, the matrix X=[0 0 0 1 1] may be replaced by a matrix Z=[0 0 1 1 1], i.e., the third column of matrix is changed to 1 from 0. Finally all the elements or solutions are fed back to the Bayesian network. The process continues until a suitable solution has been found or until difference between the total estimated power and the total measured power is not less than the power threshold.

One advantage of the described cognitive energy meter is it reduces computation through cascaded Bayesian network in APE. It further enables close to real-time appliance identification of a household. Another advantage of the meter is enablement of unsupervised learning capabilities and better appliance identification for the given household. The meter also reduces dependence on having the appliance model for all homes and it does not require field training or manual intervention.

While only certain features of the invention have been illustrated and described herein, many modifications and changes will occur to those skilled in the art. It is, therefore, to be understood that the appended claims are intended to cover all such modifications and changes as fall within the true spirit of the invention.

1. An energy measurement system comprising:
at least one sensor configured to measure at least one output signal associated with a plurality of appliances;
an orientation module configured to gather publicly available information associated with a location of the appliances;
a planning module configured to generate an appliance database based on an input signal from the orientation module;
a decomposition module configured to decompose the at least one output signal into constituent individual loads and therefrom identify energy consumption corresponding to each appliance based on the appliance database;
a communication interface configured to transmit the decomposed output signal.

2. The system of claim 1 wherein the at least one sensor, the orientation, planning, decomposition modules, and the communication interface are housed within an energy meter.

3. The system of claim 1 wherein the at least one sensor is housed within an energy meter, and wherein the orientation, planning, and decomposition modules, and the communication interface situated at a remote location.

4. The system of claim 1, further comprising at least one sensor configured to measure environmental data, and wherein the decomposition module is configured to use the environmental data.

5. The system of claim 1, wherein the at least one output signal is selected from a current signal, a voltage signal, an admittance signal, an impedance signal, a total power signal and combinations thereof.

6. The system of claim 5, wherein the decomposition module is further configured to decompose the at least one output signal based on a power difference between the total power signal and an estimated total power from the appliance database.

7. The system of claim 1, wherein the publicly available information comprises an Internet database.

8. The system of claim 7, wherein the internet database comprises an aerial imagery of a house from a Google Maps™ mapping service or a house details from Zillow.com® real estate service.

9. The system of claim 1, wherein the state matrix comprises a state of the appliance and estimated, known, or measured information about the appliance.

10. The system of claim 1, wherein the orientation module is further configured to gather information from a local information database and an appliance template database.

11. The system of claim 6, wherein the decomposition module comprises:
an appliance probability estimator configured to estimate a plurality of probabilities of energized appliances; and
an appliance combination estimator configured to generate a new combination of the plurality of probabilities of energized appliances based on the power difference.

12. The system of claim 11, wherein the appliance probability estimator comprises a Markov Chain algorithm or a hidden Markov Chain algorithm.

13. The system of claim 11, wherein the appliance probability estimator comprises a Bayesian algorithm comprising at least one classifier.

14. The system of claim 13, wherein the at least one classifier comprises a temperature classifier, a time classifier, a power classifier, a voltage classifier, a load type classifier, a geographic location classifier or any combinations thereof.

15. The system of claim 11, wherein the appliance probability estimator is further configured to generate an estimated total power based on the sum of estimated energy consumption of the individual loads.

16. The system of claim 11, wherein the appliance combinatorial estimator comprises a genetic algorithm.

17. A method for identifying energy consumption associated with at least one appliance comprising:
measuring an energy consumption signal;
obtaining publicly available information of a location of the at least one appliance;
estimating a plurality of probabilities of energized appliances based on the energy consumption signal and the publicly available information;
generating a new combination of the estimated plurality of probabilities of energized appliances; and
decomposing the at least one energy consumption signal into constituent individual loads and corresponding energy consumption.

18. The method of claim 17, wherein the energy consumption signal is selected from a current signal, a voltage signal, an admittance signal, an impedance signal, a total power signal and combinations thereof.

19. The method of claim 17, wherein the publicly available information comprises an Internet database.

20. The method of claim 17, further comprising generating an estimated total power based on the sum of estimated energy consumption of the individual loads; obtaining a difference between the energy consumption signal and the estimated total power; and
using the difference to determine whether further generation of the new combination of the estimated plurality of probabilities is required.

21. The method of claim 17, wherein estimating the plurality of probabilities comprises filtering the estimated probabilities based on a classification comprising a temperature classification, a time classification, a power classification, a voltage classification, a load type classification, a geographic location classification or any combinations thereof.

22. The method of claim 17, wherein generating the new combination comprises determining a schema based on the estimated probabilities.

23. The method of claim 17, wherein generating the new combination comprises using a genetic algorithm method.

24. The method of claim 23, wherein the genetic algorithm method comprises the steps of selection, crossover and mutation.

25. An energy measurement system comprising:
at least one sensor configured to measure at least one output signal associated with a plurality of appliances;
a communication interface configured to transmit the at least one output signal to a remote utility station;
an orientation module configured to gather publicly available information associated with a location of the appliances;
a planning module configured to generate an appliance database based on an input signal from the orientation module;
a decomposition module configured to decompose the at least one output signal into constituent individual loads and therefrom identify energy consumption corresponding to each appliance based on the appliance database;
wherein the orientation module, the planning module and the decomposition module are located at the remote utility station.
